(19) United States
(12) Patent Application Publication
(10) Pub. No.: US 2025/0185220 A1
(43) Pub. Date: Jun. 5, 2025

(54) INDOOR AND OUTDOOR AIR EXCHANGE-TYPED THERMO-HYGROSTAT

(71) Applicant: CHUNG LOCK OH, Gwangju (KR)

(72) Inventor: CHUNG LOCK OH, Gwangju (KR)

(21) Appl. No.: 18/527,235

(22) Filed: Dec. 1, 2023

(51) Int. Cl. H05K 7/20; F24F 11/00

(52) U.S. Cl. CPC H05K 7/20836; F24F 11/0001

(57) ABSTRACT

The present disclosure relates to a thermo-hygrostat that maintains the temperature and humidity in a to-be-cooled indoor space at a certain level, and more specifically, to an indoor and outdoor air exchange-typed thermo-hygrostat cooling the to-be-cooled indoor space, that is provided with a heat exchange element so that the server room can be cooled cleanly and power consumption can be reduced by using the outdoor air in winter, which has a lower temperature than the server room's set temperature.

### TECHNICAL FIELD

The present disclosure relates to a thermo-hygrostat that maintains the temperature and humidity in a to-be-cooled indoor space at a certain level, and more specifically, to an indoor and outdoor air exchange-typed thermo-hygrostat cooling the to-be-cooled indoor space, that is provided with a heat exchange element so that the server room can be cooled cleanly and power consumption can be reduced by using the outdoor air in winter, which has a lower temperature than the server room's set temperature.

### DISCUSSION OF RELATED ART

In general, air conditioning aims to maintain indoor conditions such as temperature, humidity, bacteria, odor, and airflow in a state suitable for the purpose of use of the location, thereby creating comfortable conditions for people living indoors in homes, hotels, halls, offices, computer rooms, and various industrial sites, etc. The air condition that is comfortable for people is affected by various conditions such as climatic conditions, clothing, standard of living, and health, so there is no fixed value. but it is usually aimed at a temperature of 26 to 28° C. and relative humidity of about 50% in summer, and a temperature of 20 to 22° C. and relative humidity of about 40% in winter.

However, these values are not absolute, and in order for places such as factory workshops, warehouses, laboratories, and computer rooms to fully fulfill their functions, they must be maintained in the most appropriate condition for the products produced, processed, stored, or tested there, or for the various devices operating in those places.

Air conditioning is used to prevent the quality of manufactured goods from being uneven or from producing many defective products. for example, in a tobacco factory, when chopping leaves, the humidity is relatively high to prevent them from drying out and turning into powder. in chocolate factories, the temperature is kept low to prevent the chocolate from melting and losing its shape, in the transistor manufacturing plant, dust is extremely reduced. and in the physiology laboratory, the air flow is slowed down to take into account the effect of wind on living organisms.

Among places that require thermo-hygrostat, data centers rent computer facilities and network facilities to companies and individuals or attract customers' facilities and provide services such as maintenance and repairs, and the server room of such a data center usually has a plurality of racks equipped with data servers and databases, including communication devices, installed in a row, and includes a workspace where workers can work.

For equipment including server racks, the temperature of the surrounding air rises due to the heat generated by the data servers. In this case, because equipment such as data servers do not operate smoothly in a high-temperature environment, a thermo-hygrostat that cools the air in the server room is needed. Further, in the case of parts or circuit equipment of various electronic devices installed in the server room, if humidity increases, there is a risk of electric leakage, and if humidity is too low, problems such as fire or damage to electronic components due to static electricity generation or sparks may occur.

To solve this problem, a conventional thermo-hygrostat cools and circulates the refluxing air using a refrigerant to a specified temperature and supplies it to maintain constant temperature and humidity in the server room.

In winter, even though the outdoor temperature is lower than the set temperature required for the server room, it is extremely cautious to directly cool the server room by drawing in outdoor air due to the nature of the server room, which must be maintained in a clean state. Therefore, the temperature in the server room was being cooled through the operation of the thermo-hygrostat.

As a result, a lot of power was consumed even in the winter, increasing energy costs and operating costs in the server room.

Therefore, there is a need to develop a thermo-hygrostat that can cool the server room using outdoor air in the winter and keep the server room clean by preventing the inflow of dust and foreign substances.

### SUMMARY

In order to address the above issues, the present disclosure is to provide an indoor and outdoor air exchange-typed thermo-hygrostat, in which in order to cool the indoor space without operating the evaporator and condenser, which are components of the refrigeration cycle device, in winter, when the temperature is lower than the server room's set temperature, a heat exchange element is provided as an integrated unit, and the indoor air of the server room is cooled by exchanging heat with the cold outdoor air in the heat exchange element, which reduces power consumption and improves the convenience of management and maintenance.

Further, the present disclosure is to provide an indoor and outdoor air exchange-typed thermo-hygrostat in which in the summer, when the outdoor air is at a higher temperature than the server room's set temperature, the damper is operated to absorb the heat emitted from the condenser without passing through the heat exchange element, and then discharged to the outdoors, and in winter, when the temperature is lower, through operation of the damper, outdoor air does not flow into the condensing unit and blowing unit, it passes only through the heat exchange element and is then discharged so that the outdoor air flow path can be variably controlled and the thermo-hygrostat can be operated efficiently depending on the outdoor temperature.

Further, the present disclosure is to provide an indoor and outdoor air exchange-typed thermo-hygrostat in which the space where the indoor air flows and the space where the outdoor air flows are formed independently and do not communicate with each other to prevent outdoor air from entering the indoors, and in a plate-shaped heat exchange element, the indoor air and outdoor air can flow orthogonally crossing to each other to exchange heat with each other to cool the indoor air without contact or mixing.

Further, the present disclosure is to provide an indoor and outdoor air exchange-typed thermo-hygrostat in which the heat exchange element is provided in a plate-shaped cross-flow type, thereby allowing the indoor and outdoor air to flow in a straight line without bending when indoor and outdoor air passes through a heat exchange element with high flow resistance to suppress fluid loss and the heat exchange element is attached to the thermo-hygrostat to suppress volume increase to the maximum so that heat exchange efficiency is very excellent to have excellent practicality and usability.

Further, the present disclosure is to provide an indoor and outdoor air exchange-typed thermo-hygrostat in which the space within the heat exchange unit is formed into four independent spaces by the heat exchange element, and each independent space is connected to an inlet unit, outlet unit, or outdoor space so that the function of each space, the inflow and outflow of indoor or outdoor air, is performed smoothly and smoothly, thereby setting the flow paths of indoor and outdoor air to have optimal efficiency.

Further, the present disclosure is to provide an indoor and outdoor air exchange-typed thermo-hygrostat in which the indoor air inlet, indoor air outlet, second damper, and third damper, respectively, through which indoor or outdoor air enters and exits the main body are provided, allowing indoor or outdoor air to enter and exit the main body consistently, regardless of the operating mode of the thermo-hygrostat, and depending to the operation mode's changes, the flow of indoor air or outdoor air changes only inside the main body, so the location where the indoor air is introduced or discharged does not change, providing increased convenience in installation and management of the main body.

The present disclosure includes an inlet unit 100 configured to have an indoor air inlet 110 through which indoor air flows, an outlet unit 200 configured to be disposed on a upper part of the inlet unit 100, forming a space independent from the inlet unit 100, communicates with the inlet unit 100 by the opening and closing operation of a first damper 210, provided with an evaporator 220 that exchanges heat with indoor air therein, above the first damper 210, and formed with an indoor air outlet 240 discharging a cooled indoor air, a heat exchange unit 300 configured to be disposed behind the inlet unit 100 and the outlet unit 200, form a space independent of the inlet unit 100 and the outlet unit 200, respectively, communicate with the inlet unit 100 through the opening and closing operation of a fourth damper 321 formed on an indoor side 320 facing indoors, communicate with the outlet unit 200 through a fifth damper 250, be provided with a second damper 311 for receiving outdoor air and a third damper 312 for discharging outdoor air provided on an outdoor side 310 facing outdoors, and provided with a heat exchange element 330 exchanging heat between the indoor and outdoor air and partitioning the internal space.

Further, the heat exchange unit 300 comprises an indoor air inflow space 340 communicating with the inlet unit 100 through a fourth damper 321 and receiving the indoor air from the inlet unit 100, an indoor air discharge space 350 disposed in a position opposite to the indoor air inflow space 340 and communicating with the outlet unit 200 through a fifth damper 250 to discharge the indoor air to the outlet unit 200, an outdoor air inflow space 360 receiving outdoor air into the indoors through the second damper 311, and an outdoor air discharge space 370 disposed in a position opposite to the outdoor air inflow space 360 and discharging outdoor air to the outdoors through the third damper 312.

Further, the heat exchange unit 330 comprises an indoor air inflow surface 331 that is a side to receive the indoor air and is disposed in the indoor air inflow space 340, an indoor air discharge surface 332 that is a side to discharge the indoor air and is disposed in the indoor air discharge space 350, an outdoor air inflow surface 333 that is a side to receive the outdoor air and is disposed in the outdoor air inflow space 360, and an outdoor air discharge surface 334 that is a side to discharge the outdoor air and is disposed in the outdoor air discharge space 370, and the indoor and outdoor air passing through the heat exchange element 330 intersect vertically with the partition plate 335 in between.

Further, an operating mode of the thermo-hygrostat includes a summer mode in which the indoor air is cooled by passing through the evaporator 220 and a winter mode in which the indoor air is cooled by heat exchange with the outdoor air in the heat exchange element without passing through the evaporator 220, and when operating in winter mode, the flow paths of the indoor air and outdoor air flowing into the heat exchange unit 300 are parallel, but the directions are opposite, and inside the heat exchange element 330, indoor and outdoor air moves in an ‘X’ shaped path.

Further, when the thermo-hygrostat operates in the summer mode, which cools the indoor air through heat exchange with the refrigerant of the evaporator 220, the indoor air flowing into the indoor air inlet 110 enters the outlet unit 200 through the open first damper 210, is cooled while passing through the evaporator 220 in the outlet unit 200 from the bottom to the top, and is discharged above the evaporator 220 into indoors through the indoor air outlet 240, and the second damper 311 and the third damper 312 provided on the outdoor side 310 are closed to prevent the outdoor air from entering the main body 10.

Further, when the thermo-hygrostat operates in the winter mode, which cools the indoor air through heat exchange with the outdoor air, the indoor air flowing into the indoor air inlet 110 enters the indoor air inflow space 340 of the heat exchange unit 300 through the open fourth damper 321, is cooled by outdoor air while passing through the heat exchange element 330, enters the outlet unit 200 through the open fifth damper 250 in the indoor air discharge space 350, and is discharged indoors through the indoor air outlet 240, and the outdoor air flows into the outdoor air inflow space 360 through the open second damper 311, cools the indoor air while passing through the heat exchange element 330, and is discharged outdoors through the open third damper 312 in the outdoor air discharge space

Further, the outlet unit 200 further includes a first blowing fan 230 disposed above the evaporator 220, and only cooled air stays above the evaporator 220 and is discharged indoors through the indoor air outlet 240 by the first blowing fan 230.

Further, a vertical length of the outlet unit 200 is formed to be longer than a vertical length of the inlet unit 100, and a vertical length of the heat exchange unit 300 is equal to the sum of the vertical length of the inlet unit 100 and the vertical length of the outlet unit 200.

Further, regardless of the operating mode of the thermo-hygrostat, indoor air flows into the inlet unit 100 only through the single indoor air inlet 110.

The present disclosure has an effect of providing an indoor and outdoor air exchange-typed thermo-hygrostat, in which in order to cool the indoor space without operating the evaporator and condenser, which are components of the refrigeration cycle device, in winter, when the temperature is lower than the server room's set temperature, a heat exchange element is provided as an integrated unit, and the indoor air of the server room is cooled by exchanging heat with the cold outdoor air in the heat exchange element, which reduces power consumption and improves the convenience of management and maintenance.

Further, the present disclosure has an effect of providing an indoor and outdoor air exchange-typed thermo-hygrostat in which in the summer, when the outdoor air is at a higher temperature than the server room's set temperature, the damper is operated to absorb the heat emitted from the condenser without passing through the heat exchange element, and then discharged to the outdoors, and in winter, when the temperature is lower, through operation of the damper, outdoor air does not flow into the condensing unit and blowing unit, it passes only through the heat exchange element and is then discharged so that the outdoor air flow path can be variably controlled and the thermo-hygrostat can be operated efficiently depending on the outdoor temperature.

Further, the present disclosure has an effect of providing an indoor and outdoor air exchange-typed thermo-hygrostat in which the space where the indoor air flows and the space where the outdoor air flows are formed independently and do not communicate with each other to prevent outdoor air from entering the indoors, and in a plate-shaped heat exchange element, the indoor air and outdoor air can flow orthogonally crossing to each other to exchange heat with each other to cool the indoor air without contact or mixing.

Further, the present disclosure has an effect of providing an indoor and outdoor air exchange-typed thermo-hygrostat in which the heat exchange element is provided in a plate-shaped cross-flow type, thereby allowing the indoor and outdoor air to flow in a straight line without bending when indoor and outdoor air passes through a heat exchange element with high flow resistance to suppress fluid loss and the heat exchange element is attached to the thermo-hygrostat to suppress volume increase to the maximum so that heat exchange efficiency is very excellent to have excellent practicality and usability.

Further, the present disclosure has an effect of providing an indoor and outdoor air exchange-typed thermo-hygrostat in which the space within the heat exchange unit is formed into four independent spaces by the heat exchange element, and each independent space is connected to an inlet unit, outlet unit, or outdoor space so that the function of each space, the inflow and outflow of indoor or outdoor air, is performed smoothly and smoothly, thereby setting the flow paths of indoor and outdoor air to have optimal efficiency.

Further, the present disclosure has an effect of providing an indoor and outdoor air exchange-typed thermo-hygrostat in which the indoor air inlet, indoor air outlet, second damper, and third damper, respectively, through which indoor or outdoor air enters and exits the main body are provided, allowing indoor or outdoor air to enter and exit the main body consistently, regardless of the operating mode of the thermo-hygrostat, and depending to the operation mode's changes, the flow of indoor air or outdoor air changes only inside the main body, so the location where the indoor air is introduced or discharged does not change, providing increased convenience in installation and management of the main body.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 FIG. 1 illustrates a perspective view of an indoor and outdoor air exchange-typed thermo-hygrostat according to the present disclosure;

FIG. 2 illustrates an exploded perspective view of an indoor and outdoor air exchange-typed thermo-hygrostat according to the present disclosure;

FIG. 3 illustrates an exploded perspective view of an indoor and outdoor air exchange-typed thermo-hygrostat according to the present disclosure;

FIG. 4 illustrates a perspective view showing the inlet unit and outlet unit in an indoor and outdoor air exchange-typed thermo-hygrostat according to the present disclosure;

FIG. 5 illustrates a perspective view showing the heat exchange unit in an indoor and outdoor air exchange-typed thermo-hygrostat according to the present disclosure;

FIG. 6 illustrates a schematic diagram briefly showing the heat exchange element in an indoor and outdoor air exchange-typed thermo-hygrostat according to the present disclosure;

FIG. 7 illustrates (a) an exploded perspective view and (b) a cross-sectional view showing an indoor and outdoor air exchange-typed thermo-hygrostat according to the present disclosure operating in summer mode; and

FIG. 8 illustrates (a) an exploded perspective view and (b) a cross-sectional view showing an indoor and outdoor air exchange-typed thermo-hygrostat according to the present disclosure operating in winter mode.

### DETAILED DESCRIPTION OF EXEMPLARY EMBODIMENTS

Hereinafter, Hereinafter, a preferred embodiment of the present disclosure is described with reference to the accompanying drawings so that those skilled in the art can easily implement it.

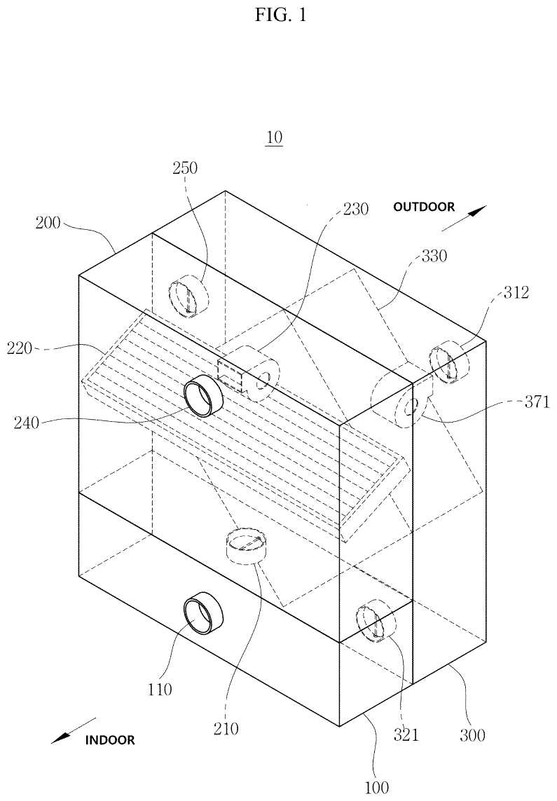

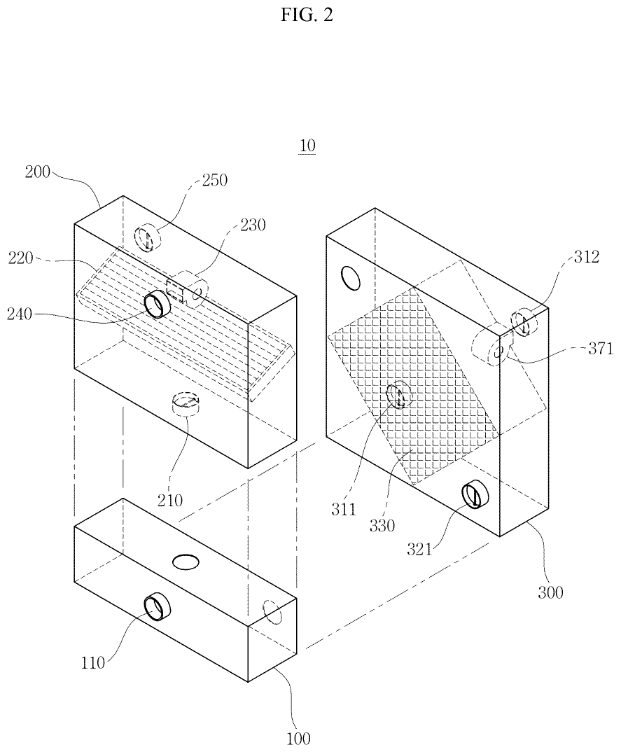

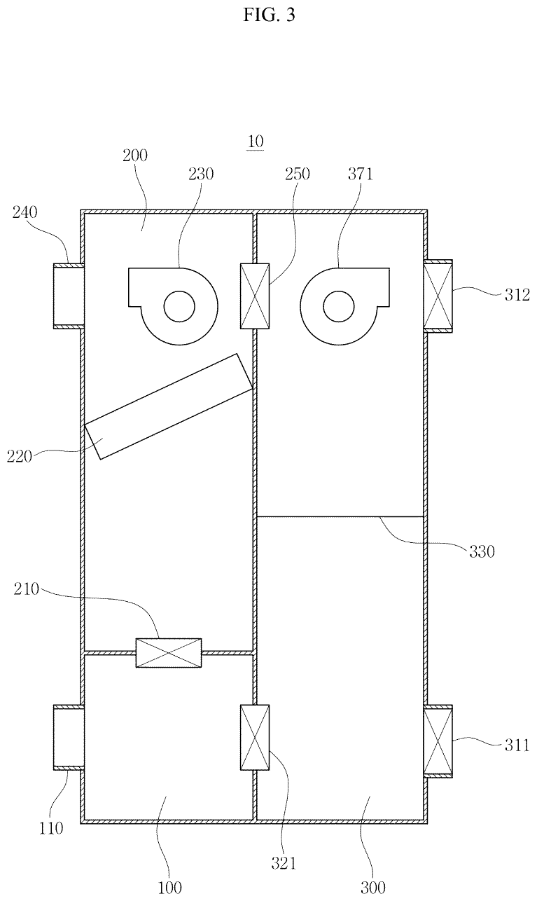

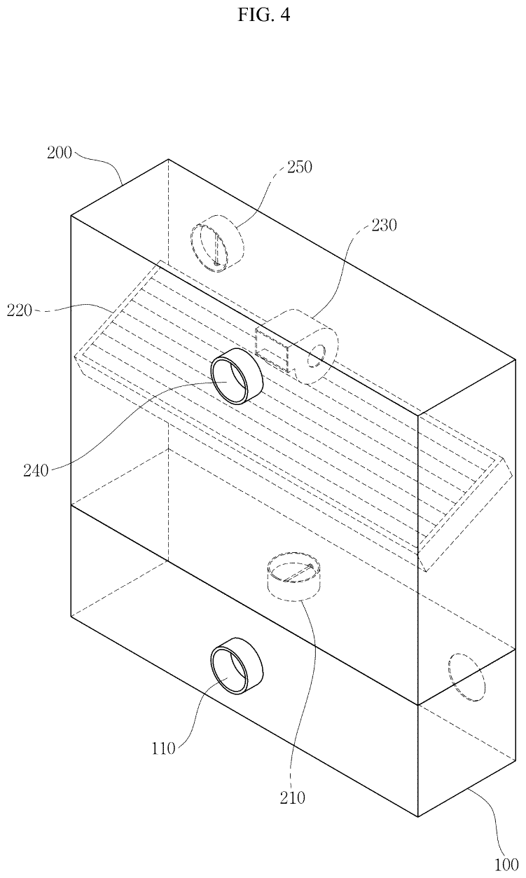

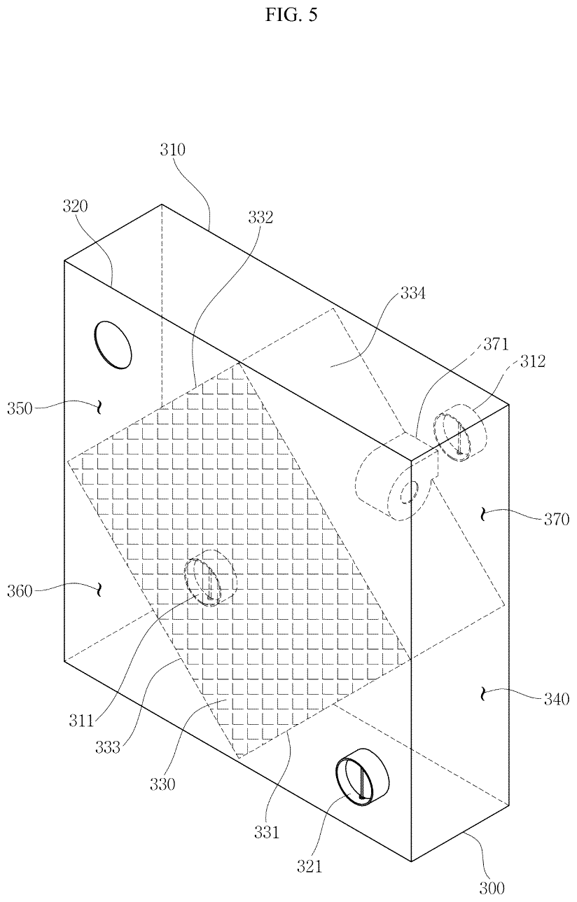

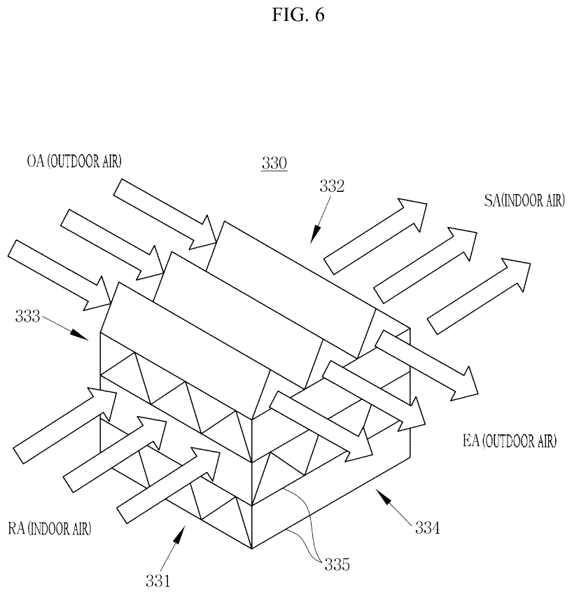

As shown in FIGS. 1 to 8, the indoor and outdoor air exchange-typed thermo-hygrostat according to the present disclosure is provided to cool the air in a server room equipped with multiple heating equipment, and it is further equipped with a heat exchange element 330 to block polluted outside air from flowing into the server room and exchanging heat with the indoor air to cool the indoor air, including an inlet unit 100 configured to have an indoor air inlet 110 through which indoor air flows, an outlet unit 200 configured to be disposed on the inlet unit 100, forming a space independent from the inlet unit 100, communicates with the inlet unit 100 by the opening and closing operation of a first damper 210, provided with an evaporator 220 that exchanges heat with indoor air therein, above the first damper 210, and formed with an indoor air outlet 240 discharging a cooled indoor air, a heat exchange unit 300 configured to be disposed behind the inlet unit 100 and the outlet unit 200, form a space independent of the inlet unit 100 and the outlet unit 200, respectively, communicate with the inlet unit 100 through the opening and closing operation of a fourth damper 321 formed on an indoor side 320 facing indoors, communicate with the outlet unit 200 through a fifth damper 250, be provided with a second damper 311 for receiving outdoor air and a third damper 312 for discharging outdoor air provided on an outdoor side 310 facing outdoors, and provided with a heat exchange element 330 exchanging heat between the indoor and outdoor air and partitioning the internal space.

The server room is equipped with multiple racks equipped with heat-generating data servers and databases. The equipment in the server room must be operated at an appropriate temperature and humidity. If the temperature and humidity are inappropriate, the equipment may not operate smoothly or a fire may occur, so a thermo-hygrostat is installed to keep the air in the server room harmonious.

Typically, the thermo-hygrostat is divided into an indoor unit equipped with the evaporator 220 that exchanges heat with the indoor air, and an outdoor unit equipped with a condenser that exchanges heat with the outdoor air, and these are installed indoors and outdoors, respectively. The present disclosure relates to an indoor unit equipped with an evaporator 220. Air heated in a server room is cooled by heat exchange with a refrigerant in the evaporator 220 and is discharged back to the server room to maintain the server room at a constant temperature.

However, when the outdoor air temperature is lower than the temperature at which the server room is set to a constant temperature state, such as in winter, rather than cooling the inside of the server room by exchanging heat with the refrigerant, cooling the inside of the server room by exchanging heat with the outside air has the advantage of reducing the power consumption required to circulate the refrigerant and saving energy. However, the server room must maintain clean air quality to prevent breakdowns in electronic equipment, so outside air cannot be accepted without filtering.

Therefore, the present disclosure is provided with an integrated heat exchange element 330 that exchanges heat between the indoor air and outdoor air inside the main body 10, which is an indoor unit so that even without operating the evaporator 220 and the outdoor condenser, which are components of the refrigeration cycle, the indoor air of the server room can be cooled by cold outdoor air and supplied to the server room, thereby maintaining a constant temperature in the server room.

In the thermo-hygrostat according to the present disclosure, when the temperature of the outdoor air is higher than the temperature of the indoor air of the server room, the indoor and outdoor air do not exchange heat to each other, but the indoor air exchanges heat with the refrigerant circulating along the refrigeration cycle to cool the server room. However, when the temperature of the outdoor air is lower than the temperature of the inside of the server room, the indoor and outdoor air do not exchange heat with the refrigerant circulating through the refrigeration cycle, and the indoor and outdoor air exchange heat each other to cool the inside of the server room.

In order to achieve this, the thermo-hygrostat of the present disclosure, the indoor of one main body 10 is divided into a total of three spaces: an inlet unit 100, an outlet unit 200, and a heat exchange unit 300, and a plurality of dampers are provided to communicate with or block each partitioned space. By opening and closing each damper, the flow paths of internal and external air are variable inside the main body 10, and along the variable flow path, the indoor air exchanges heat through a refrigerant, or the indoor air and outdoor air exchange heat with each other.

Therefore, the indoor and outdoor unit, and heat exchange element 330 are not provided in separate places but are housed inside one main body 10 to improve convenience of maintenance, and in winter, to cool the server room even without operating the evaporator 220 and outdoor condenser, which are components of the refrigeration cycle, thereby dramatically reducing power consumption.

As shown in FIGS. 1, 7, and 8, in the present disclosure, the air inside the server room is referred to as indoor air, and the air outside the server room is referred to as outdoor air. In the thermo-hygrostat of the present disclosure, indoor air is not discharged to the outdoors, outdoor air is not introduced into the indoor room, and indoor air is circulated indoors. Therefore, it is possible to block dust and foreign substances contained in the outdoor air from entering the server room and protect the equipment within the server room.

In the present disclosure, the set temperature refers to the optimal temperature that can smoothly operate electronic equipment in the server room.

Further, when explaining the operating mode of the thermo-hygrostat of the present disclosure, the mode in which the temperature of the outdoor air is higher than the set temperature and the refrigeration cycle including the evaporator 220 and the condenser is operated to cool the indoor air through the refrigerant is referred to as summer mode, and the mode in which the temperature of the outdoor air is lower than the set temperature and the indoor air is cooled by heat exchange between the indoor and outdoor air without operating the refrigeration cycle including the evaporator 220 and the condenser is referred to as winter mode.

However, the summer mode and winter mode are named after the characteristics of the season for convenience, and do not necessarily refer to modes that operate only in summer or winter. Even in spring or fall, the operating mode can be changed to summer mode or winter mode depending on the outdoor temperature. Changing the operation mode to summer mode or winter mode is determined by the set temperature of the server room and the temperature of the outdoor air.

The thermo-hygrostat according to the present disclosure is a device that cools the indoor air by operating a refrigeration cycle device consisting of four cycles: evaporation>compression>condensation>expansion. In the inside of the single body 10, in order to cool the indoor air, it is provided with the evaporator 220 that exchanges heat with the indoor air and the heat exchange element 330 that exchanges heat with the indoor and outdoor air. Here, other components such as the condenser provided in the outdoor unit, the compressor and the expansion valve that make up the refrigeration cycle are common, so their illustration and description are omitted. However, the refrigerant circulating in the refrigeration cycle moves along the interconnected evaporator 220 and condenser.

Referring to FIGS. 1 to 3, the internal space of the main body 10 is divided into the inlet unit 100, the outlet unit 200, and the heat exchange unit 300 according to its function. It is divided into three sections to form an independent internal space. Through the dampers, the inlet unit 100—the outlet unit 200, the inlet unit 100—the heat exchange unit 300, and the outlet unit 200—the heat exchange unit 300 selectively communicate with each other. The spaces listed above can be communicated or blocked to form independent spaces by controlling the opening and closing of the damper.

Further, the thermo-hygrostat according to the present disclosure may be further equipped with a humidifier or dehumidifier to control the humidity of the inside. The location is preferably located in the inlet unit 100 or the outlet unit 200. However, in the present disclosure, illustration and detailed description of the humidifier or dehumidifier are excluded.

Referring to FIGS. 1 to 4, the inlet unit 100 is a space that introduces the indoor air of the server room into the main body 10, and the indoor air inlet 110 for receiving indoor air from the server room into the main body 10 and is located at the lower part of the various spaces formed in the main body 10. The inlet unit 100 has the indoor air inlet 110 formed at its lower part for receiving the indoor air inside, and the indoor air inlet 110 faces the indoors. Only indoor air can flow into the inlet unit 100, and outside air does not flow into the inlet unit 100.

The inlet unit 100 communicates with the outlet unit 200 placed above the inlet unit 100 through the first damper 210 and communicates with the heat exchange unit 300 through the fourth damper 321.

The indoor air flowing into the indoor air inlet 110 of the inlet unit 100 moves to the outlet unit 200 through the first damper 210, or moves to the heat exchange unit 300 through the fourth damper 321 depending on the summer mode or winter mode of the thermo-hygrostat, More specifically, in the summer mode, because the indoor air exchanges heat with the refrigerant, the indoor air in the inlet unit 100 is moved to the outlet unit 200 through the open first damper 210 and is moved to the evaporator 220 provided in the outlet unit 200 to exchange heat with the refrigerant in the evaporator 220, but in the winter mode, because the indoor air exchanges heat with the cold outdoor air, the indoor air of the inlet unit 100 is moved to the heat exchange unit 300 through the open fourth damper 321 to exchange heat with the cold outdoor air in the heat exchange element 330 of the heat exchange unit 300.

The first damper 210 and the fourth damper 321 have opposite opening and closing operations. When the first damper 210 is opened, the fourth damper 321 is closed, but when the first damper 210 is closed, the fourth damper 321 is opened. The state in which the first damper 210 is open and the fourth damper 321 is closed is in the summer mode of the thermo-hygrostat, and the indoor air of the inlet unit 100 does not move to the heat exchange unit 300 due to the closed fourth damper 321 but flows into the outlet unit 200 through the open first damper 210. On the other hand, the state in which the first damper 210 is closed and the fourth damper 321 is open is in the winter mode of the thermo-hygrostat, and the indoor air in the inlet unit 100 does not move to the outlet unit 200 due to the closed first damper 210 but flows into the heat exchange unit 300 through the open fourth damper 321.

Regardless of whether the operating mode of the thermo-hygrostat is summer mode or winter mode, indoor air always flows into the indoor air inlet 110 of the inlet unit 100. The indoor air in the server room (indoor) flows into the main body 10 through the single indoor air inlet 110 so that there is no need to provide a separate hole for receiving indoor air in the summer mode of the thermo-hygrostat or a hole for receiving indoor air when in winter mode of the thermo-hygrostat. Therefore, regardless of the operating mode of the thermo-hygrostat, the indoor air flows into the indoor air inlet 110, which is a single hole, and by manipulating the damper inside the main body 10, the indoor air flow path is formed differently depending on the operation mode, and a hole exposed indoors is only one indoor air inlet 110. Therefore, the aesthetic appearance of the thermo-hygrostat of the present disclosure when exposed indoors is simplified, and only one hole, the indoor air inlet 110, can be managed and cleaned, thereby improving the convenience of maintenance.

Referring to FIGS. 1 to 4, the outlet unit 200 is a space disposed on the inlet unit 100 and is provided with the evaporator 220 that cools the indoor air by exchanging heat with the refrigerant. The evaporator 220 is provided at a higher position than the indoor air inlet 110 and the first damper 210.

It exchanges heat with the refrigerant before being cooled when indoor air flows into the inlet 100 through the first damper 210 or after flowing through the first damper 210 and passing through the evaporator 220, so that the indoor air passes through the evaporator 220 in the outlet unit 200 and then becomes cooled indoor air. Therefore, only cooled and cold indoor air may exist in the upper space of the evaporator 220 in the outlet unit 200. More specifically, in summer mode, the indoor air flows from the inlet unit 100 to the outlet unit 200 through the open first damper 210, passes through the evaporator 220 from the bottom to the top to be cooled. Therefore, the upper space of the evaporator 220 contains indoor air cooled by the evaporator 220. On the other hand, in winter mode, the indoor air is cooled by heat exchange with cold outdoor air in the heat exchange unit 300, and then flows into the upper space of the evaporator 220 through the fifth damper 250. Therefore, the upper space of the evaporator 220 contains indoor air cooled by the heat exchange unit 300. Therefore, only cooled indoor air exists in the upper space of the evaporator 220 regardless of operation mode.

The first blowing fan 230 is provided in the upper space of the evaporator 220 of the outlet unit 200 to blow cooled air into the indoors, and the indoor air outlet 240 is formed to discharge air blown from the first blowing fan 230 into the indoors.

Since the evaporator 220 and the first blowing fan 230 are provided inside the outlet unit 200, the vertical length (height) of the outlet unit 200 is formed longer than the vertical length (height) of the inlet unit 100. Further, the combined vertical length of the inlet unit 100 and the vertical length of the outlet unit 200 is the same as the vertical length (height) of the heat exchange unit 300.

The outlet unit 200 forms a space independent of the inlet unit 100 and the heat exchange unit 300, respectively, selectively communicates with the inlet unit 100 by the opening and closing operation of the first damper 210 and selectively communicates with the heat exchange unit 300 by the opening and closing operation of the fifth damper 250. The first damper 210 and the fifth damper 250 have opposite opening and closing operations. For example, when the first damper 210 is opened, the fifth damper 250 is closed, the thermo-hygrostat operates in summer mode, so that the outlet unit 200 receives the indoor air from the inlet unit 100 rather than the heat exchange unit 300, but when the first damper 210 is closed and the fifth damper 250 is open, the thermo-hygrostat operates in winter mode, so that the outlet unit 200 receives the indoor air from the heat exchange unit 300 rather than the inlet unit 100.

The first damper 210 has an opening and closing operation opposite to that of the fourth damper 321 and the fifth damper 250, and the fourth damper 321 and the fifth damper 250 perform the same opening and closing operations. That is, when the fourth damper 321 is opened, the fifth damper 250 is also open, and when the fourth damper 321 is closed, the fifth damper 250 is also closed.

Referring to FIGS. 1 to 3, 5, and 6, the heat exchange unit 300 disposed behind the inlet unit 100 and the outlet unit 200 is a space in which the indoor air and outdoor air exchange heat to cool the indoor air. The heat exchange unit 300 forms a space independent of the inlet unit 100 and the outlet unit 200, respectively, can selectively communicate with the inlet unit 100 or the outlet unit 200 by the fourth damper 321 and the fifth damper 250.

Further, the heat exchange unit 300 is provided with the heat exchange element 330 that exchanges heat with the indoor air and the outdoor air. The internal space of the heat exchange unit 300 is partitioned by the heat exchange element 330. Referring to this in detail, it is partitioned into the indoor air inflow space 340 communicating with the inlet unit 100 through the fourth damper 321 and receiving the indoor air from the inlet unit 100, the indoor air discharge space 350 disposed in a position opposite to the indoor air inflow space 340 based on the heat exchange element 330 and communicating with the outlet unit 200 through the fifth damper 250 to discharge the indoor air to the outlet unit 200, the outdoor air inflow space 360 provided with the second damper 311 receiving outdoor air into the indoors, and the outdoor air discharge space 370 disposed in a position opposite to the outdoor air inflow space 360 and provided with the second blowing fan 371 to discharge outdoor air to the outdoors.

In the heat exchange unit 300, the indoor air moves from the indoor air inlet space 340 across the heat exchange element 330 to the indoor air discharge space 350, but the outdoor air moves from the outdoor air inlet space 360 across the heat exchange element 330 to the outdoor air discharge space 370.

The heat exchange unit 300 includes the indoor side 320, which is a side facing indoors, and the outdoor side 310, which is a side facing outdoors. The indoor side 320 faces the indoors but is not exposed to the indoors as it is covered by the inlet unit 100 and the outlet unit 200.

The second damper 311 and the third damper 312, which are dampers through which outdoor air enters and exits the heat exchange unit 300, are provided on the outdoor side 310, but the fourth damper 321 and the fifth damper 250, which are dampers through which indoor air enters and exits the heat exchange unit 300, are provided on the indoor side 320.

The fourth damper 321 and the fifth damper 250, and the second damper 311 and third damper 312 are dampers that allow air to enter and exit the heat exchange unit 300. The opening and closing operations of the fourth damper 321 and the fifth damper 250 are the same, and the fourth damper 321 and the fifth damper 250 are opened or closed at the same time. The opening and closing operations of the second damper 311 and the third damper 312 are also the same. and the second damper 311 and the third damper 312 are opened or closed at the same time.

When the thermo-hygrostat is in the summer mode, the indoor air is cooled in the evaporator 220, so it does not pass through the heat exchange unit 300, and the outdoor air exchanges heat with the condenser in the outdoor unit provided in a separate location from the main body 10. Therefore, indoor and outdoor air does not enter or exit the heat exchange unit 300. That is, in summer mode, the fourth damper 321 and the fifth damper 250, and the second damper 311 and third damper 312 are closed. However, in winter mode, indoor air and outdoor air enter and exit the heat exchange unit 300 to exchange heat with each other inside. Accordingly, the fourth damper 321 and the fifth damper 250, and the second damper 311 and third damper 312 are opened, and indoor air and outdoor air enter and exit the heat exchange unit 300.

The heat exchange element 330 provided in the heat exchange unit 300 is an element that exchanges heat without mixing indoor air and outdoor air as they pass through. The heat exchange element 330 of the present disclosure is provided in a cross-flow form in which the indoor air and outdoor air cross vertically and exchange heat with each other, and the space where the indoor air and outdoor air move is separated by the partition plate 335. However, they exchange heat with each other by the partition plate 335, which has excellent heat permeability.

The heat exchange unit 330 comprises the indoor air inflow surface 331 that is a side to receive the indoor air, the indoor air discharge surface 332 that is a side to discharge the indoor air, the outdoor air inflow surface 333 that is a side to receive the outdoor air, and the outdoor air discharge surface 334 that is a side to discharge the outdoor air. The indoor air inflow surface 331 is disposed in the indoor air inflow space 340, the indoor air discharge surface 332 is disposed in the indoor air discharge space 350, the outdoor air inflow surface 333 is disposed in the outdoor air inflow space 360, and the outdoor air discharge surface 334 is disposed in the outdoor air discharge space 370.

The indoor air in the indoor air inflow space 340 passes through the heat exchange element 330 through the indoor air inflow surface 331, is discharged from the indoor air discharge surface 332 and moves to the indoor air discharge space 350, but outdoor air in the outdoor air inflow space 360 passes through the heat exchange element 330 through the outdoor air inflow surface 333, is discharged from the outdoor air discharge surface 334 and moves to the outdoor air discharge space 370.

At this time, the flow directions of the indoor and the outdoor air passing through the heat exchange element 330 are orthogonal to each other, and the indoor air and the outdoor air exchange heat with each other across the partition plate 335.

The heat exchange element 330 of the present disclosure is provided in a cross-flow form so that the indoor air and the outdoor air exchange heat directly without any other medium such as a refrigerant, but are separated by the partition plate 335, thereby preventing mixing. Therefore, despite its volume, it has a very high heat exchange efficiency, no risk of the indoor air being polluted by outdoor air, and an effect of minimizing the volume.

In summer mode, the indoor and outdoor air do not pass through the heat exchange element 330. Only in winter mode, mutual heat exchange occurs as indoor and outdoor air passes through the heat exchange element 330.

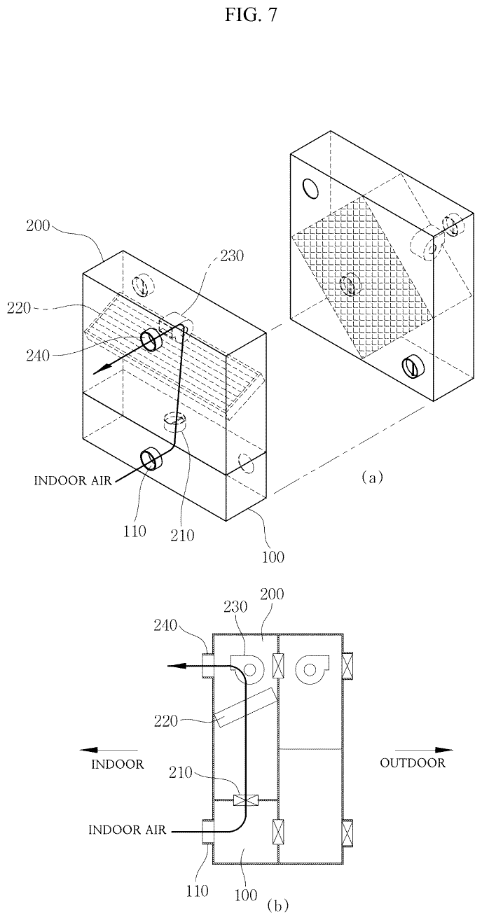

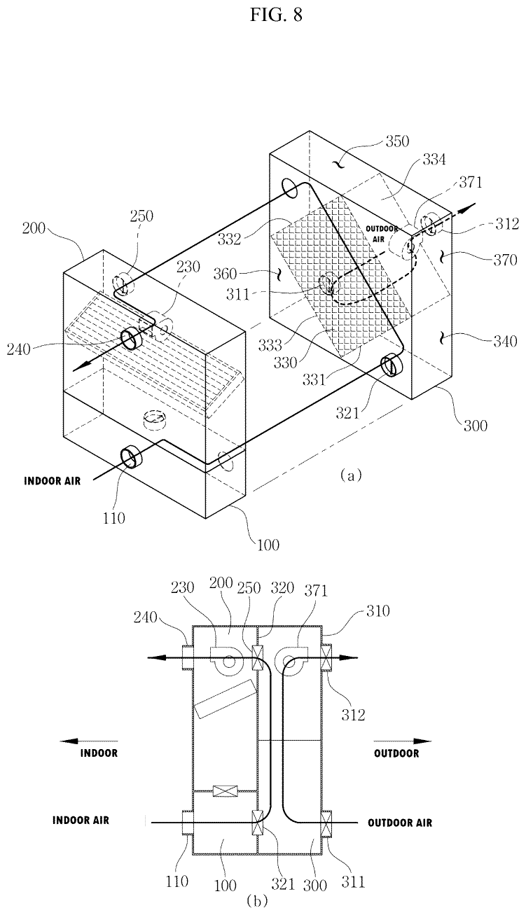

Hereinafter, with reference to FIGS. 7 and 8, the flow of indoor and outdoor is described in detail according to the operation mode of the indoor and outdoor air exchange-typed thermo-hygrostat of the present disclosure.

Summer mode is a mode that operates the refrigeration cycle to cool the indoor air through heat exchange with the refrigerant when the temperature of the outside air is higher than the set temperature of the server room so that the indoor air cannot be cooled.

As shown in FIG. 7, referring to the flow path of indoor air when the thermo-hygrostat is operated in summer mode, indoor air in the server room flows into the inlet unit 100 through the indoor air inlet 110. At this time, the force for the indoor air to flow into the indoor air inlet 110 is generated by the suction force caused by the operation of the first blowing fan 230. The fourth damper 321 of the inlet unit 100 is closed, so the indoor air flowing into the inlet unit 100 does not move to the heat exchange unit 300 and passes through the open first damper 210 and enters (moves to) the outlet unit 200.

As the indoor air passes through the evaporator 220 located above the first damper 210 in the outlet unit 200, it is cooled while exchanging heat with the refrigerant of the evaporator 220. It passes through the evaporator 220 from the lower part to the upper part, is sucked in by the first blowing fan 230 placed above the evaporator 220 and is discharged into the indoors (server room) through the indoor air outlet 240. At this time, the fifth damper 250 of the outlet unit 200 is closed, and the indoor air of the outlet unit 200 does not move to the heat exchange unit 300.

In summer mode, outdoor air does not enter or exit the main body 10 but passes through the condenser of the outdoor unit provided in a separate location from the main body 10 and cools the refrigerant by exchanging heat with the refrigerant.

In winter mode, when the temperature of the outdoor air is lower than the set temperature of the server room to cool the indoor air, heat may be exchanged between the indoor air and the outdoor air to cool the indoor air even without operating the refrigeration cycle including the evaporator 220 and the condenser, thereby saving energy.

Referring to the flow path of the indoor air in winter mode in reference with FIG. 8, the indoor air in the server room flows into the inlet unit 100 through the indoor air inlet 110. In winter mode, the force that causes the indoor air to flow through the indoor air inlet 110 is generated by the suction force caused by the operation of the first blowing fan 230. Further, regardless of whether the thermo-hygrostat is operated in summer mode or winter mode, even if the indoor air inlet 110 is provided as a single, the indoor air can be received through the single indoor air inlet 110. By opening and closing the first damper 210 and the fourth damper 321, the flow path of the indoor air according to each operation mode can be variably formed inside the main body 10.

The indoor air flowing into the inlet unit 100 does not directly enter the outlet unit 200 due to the closed first damper 210 but moves to the the indoor air inflow space of the heat exchange unit 300 through the open fourth damper 321. It enters the inside of the heat exchange element 330 through the indoor air inlet surface 331 in the indoor air inflow space 340, is cooled by the cold outdoor air passing through the heat exchange element 330, then is discharged from the indoor air discharge surface 332 and moves to the indoor air discharge space 350.

The indoor air in the indoor air discharge space 350 moves to the outlet unit 200 through the open fifth damper 250 and is discharged indoors through the indoor air outlet 240 by the first blowing fan 230. At this time, the fifth damper 250, the first blowing fan 230, and the indoor air outlet 240 are disposed above the evaporator 220, and the first damper 210 is closed so that the indoor air flowing into the outlet unit 200 through the fifth damper 250 does not enter the inlet unit 100 again and is discharged directly into the indoors without passing through the evaporator 220. Therefore, the flow path of the indoor air is not unnecessarily diverted and is set optimally.

Referring to the outdoor air flow path in winter mode, outdoor air flows into the outdoor air inflow space 360 of the heat exchange unit 300 through the opened second damper 311. At this time, the force that introduces outdoor air into the outdoor air inflow space 360 is generated from the suction force caused by the operation of the second blowing fan 371.

The outdoor air of the outdoor air inflow space 360 enters the inside of the heat exchange element 330 through the outdoor air inflow surface 333 and cools the indoor air by exchanging heat with the indoor air. Further, it is discharged from the outdoor air discharge surface 334, moves to the outdoor air discharge space 370, and is discharged outdoors through the open third damper 312 by the second blowing fan 371.

The indoor and outdoor air are separated by the partition plate 335, so that they do not mix with each other, but heat is exchanged by the partition plate 335, which has excellent heat permeability.

At this time, the indoor air flow path in winter mode forms a longer travel distance than the indoor air flow path in summer mode.

Further, referring to the flow paths of the indoor and outer air shown in shown in FIG. 8, the flow paths of the indoor air and outdoor air flowing into the heat exchange unit 300 are parallel, but the directions are opposite, and the flow paths of the indoor air and outdoor air discharged from the heat exchange unit 300 are parallel but the directions are opposite. In the heat exchange element 330, indoor and outdoor air moves in an ‘X’ shaped path.

Various changes in form or detail may be made to the present disclosure by one of ordinary skill in the art without departing from the scope of the present disclosure, and the present disclosure is not limited to the above-described embodiments and the accompanying drawings.

What is claimed is:

1. An indoor and outdoor air exchange-typed thermo-hygrostat comprising:
an inlet unit configured to have an indoor air inlet through which indoor air flows;
an outlet unit configured to be disposed on the inlet unit, forming a space independent from the inlet unit, communicates with the inlet unit by the opening and closing operation of a first damper, provided with an evaporator that exchanges heat with indoor air therein, above the first damper, and formed with an indoor air outlet discharging a cooled indoor air;
a heat exchange unit configured to be disposed behind the inlet unit and the outlet unit, form a space independent of the inlet unit and the outlet unit, respectively, communicate with the inlet unit through the opening and closing operation of a fourth damper formed on an indoor side facing indoors, communicate with the outlet unit through a fifth damper, be provided with a second damper for receiving outdoor air and a third damper for discharging outdoor air provided on an outdoor side facing outdoors, and provided with a heat exchange element exchanging heat between the indoor and outdoor air and partitioning the internal space.

2. The indoor and outdoor air exchange-typed thermo-hygrostat of claim 1, wherein the heat exchange unit comprises:
an indoor air inflow space communicating with the inlet unit through a fourth damper and receiving the indoor air from the inlet unit;
an indoor air discharge space disposed in a position opposite to the indoor air inflow space and communicating with the outlet unit through a fifth damper to discharge the indoor air to the outlet unit;
an outdoor air inflow space receiving outdoor air into the indoors through the second damper; and
an outdoor air discharge space disposed in a position opposite to the outdoor air inflow space and discharging outdoor air to the outdoors through the third damper.

3. The indoor and outdoor air exchange-typed thermo-hygrostat of claim 2, wherein the heat exchange unit comprises:
an indoor air inflow surface that is a side to receive the indoor air and is disposed in the indoor air inflow space;
an indoor air discharge surface that is a side to discharge the indoor air and is disposed in the indoor air discharge space;
an outdoor air inflow surface that is a side to receive the outdoor air and is disposed in the outdoor air inflow space; and
an outdoor air discharge surface that is a side to discharge the outdoor air and is disposed in the outdoor air discharge space, and
wherein the indoor and outdoor air passing through the heat exchange element intersect vertically with the partition plate in between.

4. The indoor and outdoor air exchange-typed thermo-hygrostat of claim 1,
wherein an operating mode of the thermo-hygrostat includes a summer mode in which the indoor air is cooled by passing through the evaporator and a winter mode in which the indoor air is cooled by heat exchange with the outdoor air in the heat exchange element without passing through the evaporator, and
wherein when operating in winter mode, the flow paths of the indoor air and outdoor air flowing into the heat exchange unit are parallel, but the directions are opposite, and inside the heat exchange element, indoor and outdoor air moves in an ‘X’ shaped path.

5. The indoor and outdoor air exchange-typed thermo-hygrostat of claim 2, wherein when the thermo-hygrostat operates in the summer mode, which cools the indoor air through heat exchange with the refrigerant of the evaporator,
the indoor air flowing into the indoor air inlet enters the outlet unit through the open first damper, is cooled while passing through the evaporator in the outlet unit from a lower part to an upper part, and is discharged above the evaporator into indoors through the indoor air outlet; and
the second damper and the third damper provided on the outdoor side are closed to prevent the outdoor air from entering the main body.

6. The indoor and outdoor air exchange-typed thermo-hygrostat of claim 2, wherein when the thermo-hygrostat operates in the winter mode, which cools the indoor air through heat exchange with the outdoor air,
the indoor air flowing into the indoor air inlet enters the indoor air inflow space of the heat exchange unit through the open fourth damper, is cooled by outdoor air while passing through the heat exchange element, enters the outlet unit through the open fifth damper in the indoor air discharge space, and is discharged indoors through the indoor air outlet; and
the outdoor air flows into the outdoor air inflow space through the open second damper, cools the indoor air while passing through the heat exchange element, and is discharged outdoors through the open third damper in the outdoor air discharge space.

7. The indoor and outdoor air exchange-typed thermo-hygrostat of claim 1, wherein the outlet unit further includes a first blowing fan disposed above the evaporator, and
wherein only cooled air stays above the evaporator and is discharged indoors through the indoor air outlet by the first blowing fan.

8. The indoor and outdoor air exchange-typed thermo-hygrostat of claim 1, wherein a vertical length of the outlet unit is formed to be longer than a vertical length of the inlet unit; and
wherein a vertical length of the heat exchange unit is equal to the sum of the vertical length of the inlet unit and the vertical length of the outlet unit.

9. The indoor and outdoor air exchange-typed thermo-hygrostat of claim 4, wherein regardless of the operating mode of the thermo-hygrostat, indoor air flows into the inlet unit only through the single indoor air inlet.
